(19) United States
(12) Patent Application Publication
(10) Pub. No.: US 2008/0289575 A1
(43) Pub. Date: Nov. 27, 2008

(54) METHODS AND APPARATUS FOR DEPOSITING A GROUP III-V FILM USING A HYDRIDE VAPOR PHASE EPITAXY PROCESS

(76) Inventors: Brian H. Burrows, San Jose, CA (US); Nyi O. Myo, San Jose, CA (US); Ronald Stevens, San Ramon, CA (US); Jacob Grayson, Santa Clara, CA (US); Lori D. Washington, Union City, CA (US); Sandeep Nijhawan, Los Altos, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/753,376

(22) Filed: May 24, 2007

(51) Int. Cl. C23C 16/08

(52) U.S. Cl. 118/715; 117/84

(57) ABSTRACT

An improved method and apparatus for depositing a Group III-V for a hydride vapor phase epitaxy (HVPE) process are provided. In one embodiment, an apparatus for a hydride vapor phase epitaxy process may include an elongated body having a trough defined between a first and a second wall, a channel formed in the first wall configured to provide a gas to the trough, and an inlet port formed in the body coupled to the channel. In another embodiment, a method for a hydride vapor phase epitaxy process may include providing Group III metal liquid precursor in a container disposed in a chamber, flowing a halogen containing gas across the container to form a Group III metal halide vapor to a reacting zone in the chamber, and mixing the Group III metal halide vapor with a Group V gas supplied in the chamber in the reacting zone.

### BACKGROUND OF THE DISCLOSURE

1. Field of the Invention

The present invention relates to methods and apparatus for depositing a Group III-V film on a substrate by a hydride vapor phase epitaxy (HVPE) process.

2. Description of the Background Art

Exptaxial Group III-V layers are widely used in optoelectronics. In particular, intense blue to ultraviolet light emitting diodes (LED) are fabricated by gallium nitride (GaN) layers. Since nitrogen has high electronegaticity, GaN has a crystal structure of wurtzite in a stable state and has a crystal structure of zinc-blende in a metastable state. Additionally, GaN crystal includes a plurality of unit cells with predetermined lattice constant at room temperature, thereby assisting the GaN film to remain in a stable state while applying at ambient environment. The stable crystal structure and desired lattice constant make GaN film a promising candidate for manufacturing blue light emitting diodes (LED).

Several technologies have been developed to grow Group III-V semiconductors, such as metal organic chemical vapor deposition (MOCVD), molecular beam epitaxy (MBE) and hydride vapor phase epitaxy (HVPE). Hydride vapor phase epitaxy (HVPE) process offers several advantages, such as high growth rate, simplicity, and low manufacturing cost compared to other conventional techniques. HVPE processes for growing Group III-V are generally performed in a reactor having a temperature controlled environment to assure the stability of Group III agent used in the process. Group III agents provided by a Group III source, such as Ga metal source, in the reactor reacts with HCl gas, forming Group III halide vapor. A Group V agent, such as ammonia (NH₃), is subsequently transported vapor by a separate gas line to a reacting zone in the reactor where it may mix with the Group III halide vapor, such as GaCl. A carrier gas is used to carry Group III halide and Group V vapor towards the substrate within the reactor. The mixed Group III halide, such as GaCl, and Group V vapor, such as ammonia (NH₃), carried by the carrier gas is subsequently eptaxial grown into a Group III-V layer (GaN) on the substrate surface. The film quality, uniformity and deposition rate may depend in part upon consistent mixing of precursors across the substrate.

Therefore, there is a need for an improved apparatus for growing a Group III-V film on a substrate by a hydride vapor phase epitaxy (HVPE) process.

### SUMMARY OF THE INVENTION

The present invention provides improved methods and apparatus for depositing a Group III-V using a hydride vapor phase epitaxy (HVPE) process. In one embodiment, an apparatus for a hydride vapor phase epitaxy process may include an elongated body having a trough defined between a first and a second wall, a channel formed in the first wall configured to provide a gas to the trough, and an inlet port formed in the body coupled to the channel.

In another embodiment, an apparatus for a hydride vapor phase epitaxy process may include a chamber, a substrate support assembly adapted to receive a substrate disposed thereon, an elongated body having a trough defined between a first and second walls disposed in the chamber proximate the substrate support assembly, an outer inlet port formed in the elongated body, a gas dispense assembly attached to the elongated body, and an inlet port and an outlet port each formed above the first and the second wall of the trough.

In yet another embodiment, a method for a hydride vapor phase epitaxy process may include providing Group III metal liquid precursor in a container disposed in a chamber, flowing a halogen containing gas across the container to form a Group III metal halide vapor to a reacting zone in the chamber, and mixing the Group III metal halide vapor with Group V gas supplied in the chamber in the reacting zone.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a top view of one embodiment of a hydride vapor phase epitaxy process chamber in accordance with the invention;

FIG. 2 depicts an enlarged partial perspective view of one embodiment of a metal precursor container disposed in the hydride vapor phase epitaxy process chamber of FIG. 1;

FIG. 3 depicts another perspective view of the contain of FIG. 2;

FIG. 4 depicts a cross section view of a metal precursor container disposed in the hydride vapor phase epitaxy process chamber of FIG. 1 during processing;

FIG. 5 depicts a cross section view of another embodiment of a metal precursor container according to the present invention; and

FIG. 6 depicts a cross section view of another embodiment of a metal precursor container according to the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides a method and apparatus for depositing a Group III-V film on a substrate surface using a hydride vapor phase epitaxy (HVPE) process. The invention provides a good control of a gas precursor mixture comprising Group III metal and Group V vapor, thereby enabling reliable and repeatable Group III-V film deposition with desired film properties and crystal structure on a substrate.

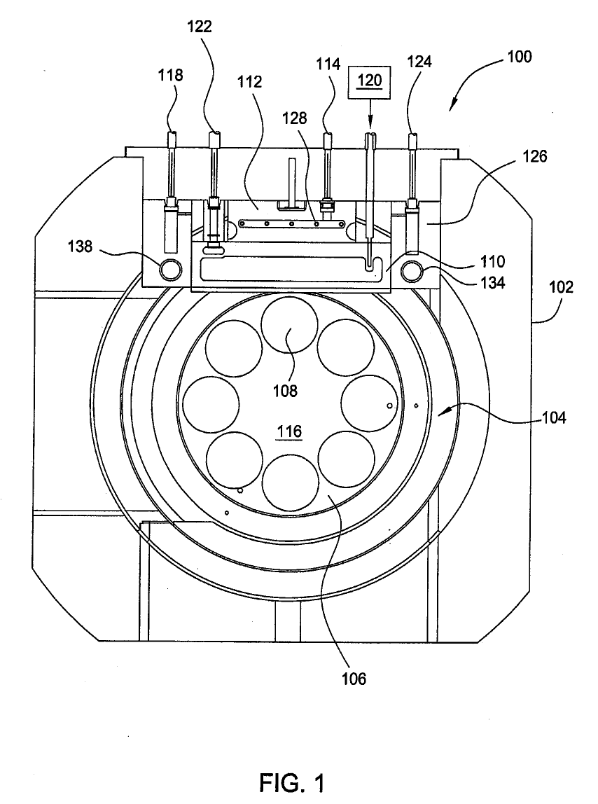

FIG. 1 depicts a top view of one embodiment of a hydride vapor phase epitaxy (HVPE) process chamber 100 in which the invention may be practiced. One suitable hydride vapor phase epitaxy (HVPE) process chamber that may be adapted to benefit from the invention is available from Applied Materials, Inc., Santa Clara, Calif. It is contemplated that other hydride vapor phase epitaxy (HVPE) process chambers, including those from other manufactures, may be adapted to practice the present invention.

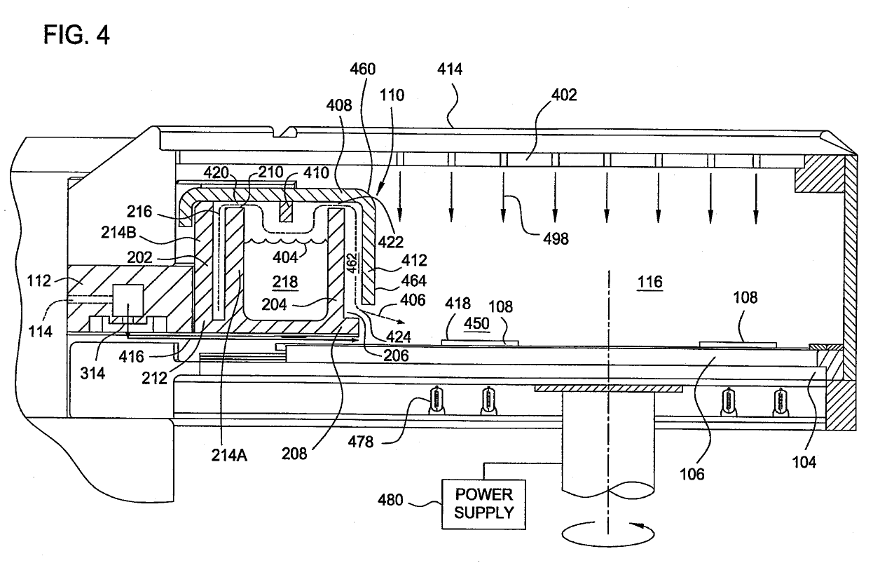

The chamber 100 generally includes a chamber body 102 having a processing region 116 defined therein. A substrate support assembly 104 is disposed in the processing region 116 having a substrate carrier 106 configured to receive a plurality of substrates 108 positioned thereon. A heating element (shown as 478 in FIG. 4) may be embedded in the substrate support assembly 104 configured to maintain the substrates 108 at a desired temperature range. In one embodiment, the substrate temperature may be maintained at a range between about 900 degrees Celsius and about 1200 degrees Celsius. The substrate carrier 106 may be connected to a power surface (shown as 480 in FIG. 4) to rotate the substrate carrier 106 during processing. The rotation of the substrate carrier 106 enhances the uniformity of films deposited on each substrate 108. In one embodiment, the substrate carrier 106 may be rotated at a speed between about 1 rpm and about 100 rpm.

A metal precursor container 110 is disposed radially outward of the substrate support assembly 104 and configured to provide Group III metal agent for processing. Examples of Group III metals include gallium (Ga), aluminum (Al), indium (In) and the like. In one embodiment, the metal precursor container 110 may be fabricated by a corrosive resist material, such as quartz, glass, polymer, ceramic, or other materials substantially inert to halogen containing gas. Suitable examples of the material for fabricating the metal precursor container 110 include sapphire and quartz. In the embodiment depicted in FIG. 1, the metal precursor container 110 is fabricated from quartz.

A gas inlet port 122 may be connected to the container 110 to supply a first reacting gas to the container 110. The gas inlet port 122 prevents the first reacting gases from pre-mixing or pre-reacting with other reacting gases from other sources supplied into the chamber 100 before entering into the processing region 116. The first reacting gases provided from the gas inlet port 122 flows across the container 110 to react with metal precursor disposed therein. In one embodiment, the first reacting gas is a halogen containing gas. Examples of halogen elements include chlorine (Cl), bromine (Br), and iodine (I). In the embodiment depicted in the present invention, the second reacting gas provided through the gas inlet port 122 is HCl gas.

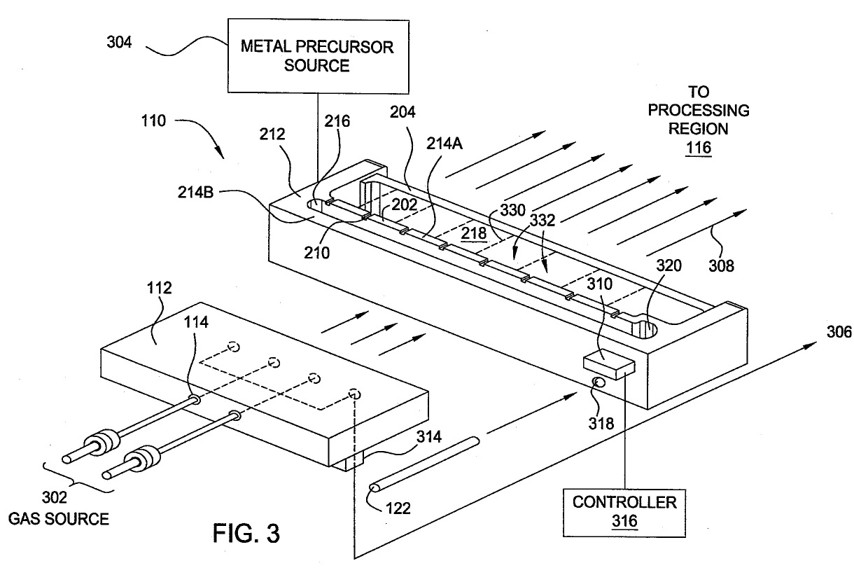

A gas dispense assembly 112 is positioned adjacent to a sidewall of the metal precursor container 110 to supply the second reacting gas through a gas inlet port 114 to the processing region 116. The gas inlet port 114 formed in the gas dispense assembly 112 may supply the second reacting gas to the processing region 116 through a plurality of apertures 128 formed on a bottom side of the gas dispense assembly 112 (shown as 314 in FIG. 3). The separate gas dispense assembly 112 may prevent the second reacting gas from pre-mixing and/or pre-acting with the first reacting gas before entering into the processing region 116. The apertures 128 direct the second reacting gas to flow below the container 110 to the processing region 116, as will be further discussed below with reference to FIG. 4. In one embodiment, the gas dispense assembly 112 may supply a Group V containing gas, such as a nitrogen containing gas, into the processing region 116. Alternatively, the gas dispense assembly 112 may also provide carrier and/or inert gas, such as N₂, H₂, NH₃, He, and Ar, among others. In the embodiment depicted herein, the gas inlet port 114 is configured to supply NH₃ gas below the container 110 to the processing region 116.

A metal precursor source 120 (also shown as 304 in FIG. 3) provides and refills metal precursor to the container 110. The metal precursor source 120 may be in form of a remote reservoir or a metal precursor. Exemplary types of metal precursor sources 120 will be further discussed in detail below with reference to FIG. 3.

A gas manifold 126 may be disposed adjacent to each end of the container 110. Inert gas and/or purge gas are provided to the manifold 126 through inlet ports 118, 124 and flow into to the processing region 116 through outlet ports 138, 134 formed in the manifold 126. Different inert gas and/or purge gas may be supplied from the outlet ports 138, 134 to the chamber 100 to direct the gas flow from other gas inlet ports 114, 122 to desired regions of the chamber 100. In one embodiment, the ports, 138, 134 are coupled to a gas distribution plate positioned over the support 116 so that the vapor leaving the container 110 mixes with the second reacting gas over the substrates 108. Additionally, the inert gas and/or purge gas from the outlet ports 138, 134 may prevent the second gas flow entering the container 110, thereby preventing films from being formed on undesired regions in the chamber 100. In one embodiment, the inert gas and/or purge gas may include N₂, H₂, N₂O, NO₂, O₃, He, Ar, and Kr among others.

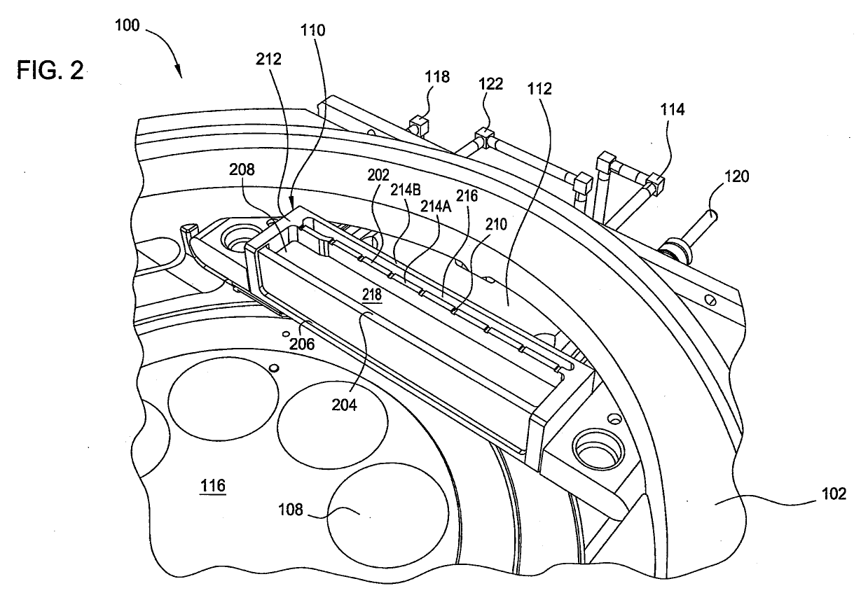

FIG. 2 depicts an enlarged perspective view of the metal precursor container 110 disposed in the processing chamber 100. The metal precursor container 110 includes an elongated body 212 having a first wall 202, a second wall 204 and a bottom wall 208 bounding an elongated trough 218 therebetween. The first wall 204 has a channel 216 formed therein, splitting a portion of the first wall 202 into an inner wall 214A and an outer wall 214B. The gas inlet port 122 is attached to or disposed against the outer wall 214B of the elongated body 212 and provides gas to the trough 218 through the channel 216.

At least one groove 210 is formed on an upper surface of the inner wall 214A to facilitate gas flow from the channel 216 to the trough 218. The grooves 210 create a restriction so the first reacting gas provided from the gas inlet port 122 uniformly distributed across the top of the channel 216. As the channel 216 is substantially filled with the reacting gas, the reacting gas flows through the grooves 210 to the trough 218. The configuration of the channel 216 provides a buffer zone or plenum for the reacting gas provided by the gas inlet port 122 to uniformly be provided to the grooves 210, thus resulting in a uniform and well-controlled flow of the first reacting gas to the trough 218. The numbers, shape, depth, distribution, and designs of the channel 216 and the grooves 210 may be varied to meet different process requirements.

In one embodiment, the bottom wall 208 of the body 212 extends beyond the second wall 204, thereby defining a recess 206 along the outer surface of the second wall 204. The recess 206 forms a slot when a container lid is disposed on the metal precursor container 110 to cover the trough 218 to direct the reacting gases to the processing region 116, as will be detail described below with reference to FIGS. 4-6. In one embodiment, the recess 206 has a depth of between about 0.4 mm and about 2 mm. It is contemplated that all or a portion of the recess 206 may be formed in the container lid (shown as 462 in FIG. 4).

The trough 218 may be filled with an amount of Group III metal precursor sufficient to react with the reacting gas from the gas supplying assembly 112. The Group III metal precursor filling in the trough 218 provides a source material that reacts with the first reacting gas and further forms a metal nitride layer on the substrate surface when mixed with the second reacting gas. In some embodiments, the metal precursor may be a solid metal material, such as bulk Ga. In some embodiments, the metal precursor may be in liquid form, such as liquid Ga metal. In some embodiments depicted in the present invention, the metal precursor may be in form of Ga-containing liquid. In some embodiments, the metal precursor may fill in the container 110 by the metal precursor source 120 to about between about 300 cubic centimeters and about 100 cubic centimeters or greater. In another embodiment, the metal precursor may fill in the container 110 by the metal precursor source 120 to about 1 mm or greater below the top of the second wall 204.

FIG. 3 depicts a perspective view of the metal precursor container 110 having the gas dispense assembly 112 exploded therefrom. The gas dispense assembly 112 and the metal precursor container 110 may be formed as a unitary body. Alternatively, the gas dispense assembly 112 may be coupled to the container 110, for example, upon installation of the container 110 into the process chamber 100. The second reacting gases are supplied from a gas source 302 to the gas dispense assembly 112. The gas source may supply one or more different second reacting gases. A bottom port 314 is formed on the bottom surface of the gas dispense assembly 112 to flow the second reacting gases into the processing region 116, for example, in a path underneath the container 110, as shown by arrow 306. An channel inlet port 318 is formed on the outer wall 214B of the body 212 to facilitate transfer the first reacting gases from the gas inlet port 122 to the channel 216 of the container 110. This configuration prevents the reacting gases from pre-mixing and pre-reacting before entering into the processing region 116, thereby avoiding pre-reaction or film pre-deposition on the undesired location in the chamber 100 and/or coating of the Ga material disposed in the trough 218.

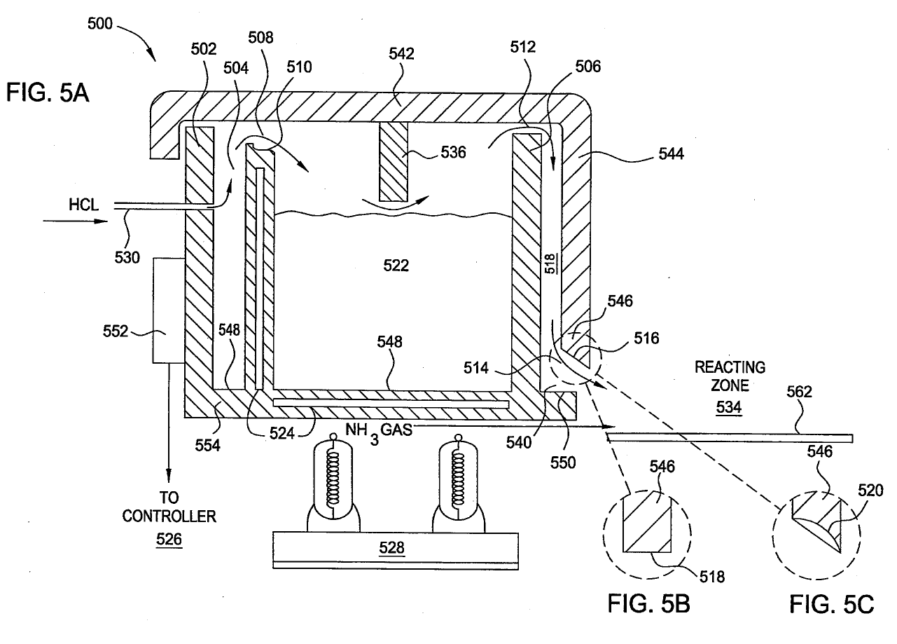

A heating element (shown as 524 in FIG. 5) is embedded in the elongated body 212 to maintain the container 110 within a desired temperature range. As different metal precursors may have different vaporization or melting point, the container temperature may significantly influence the gas phase/liquid phase transition of the metal precursor. In one embodiment, the heating element may maintain the container at a temperature between about 500 degrees Celsius and about 900 degrees Celsius. In some embodiment, the temperature of the body is controlled to maintain the metal in a liquid state. Alternatively, the container temperature may be controlled to a desired physical condition of the metal precursor disposed in the container 110.

A temperature detector 310 may be interfaced with to the metal precursor container 110 to monitor the container temperature and enable feed back for temperature control. In one embodiment, the temperature detector 310 may be a thermocouple coupled to the body 212, a remote pyrometric sensor, or other suitable temperature monitor device. In another embodiment, the temperature detect 310 may be in form of a device remote from the body having a detecting probe attaching to the body 212 through an aperture (not shown) formed in the body 212. The temperature detector 310 is coupled to a controller 316 to provide feed back loop for controlling the endpoint of the heating element, thereby enhancing temperature control.

In one embodiment, another configuration of a metal precursor source 304 different from the metal precursor source 120 of FIG. 1 may be coupled to the metal precursor container 110 to refill the metal precursor in the trough 218 as needed. In one embodiment, the metal precursor source 304 may supply metal precursor into the trough 218 through an injector internally or externally in or around the chamber 100. In another embodiment, metal precursor source 304 may be in form of a crucible external to the chamber 100 connecting to the metal precursor container 110 by a tube. In yet another embodiment, the metal precursor source 304 may, be an internal reservoir disposed and connected to the container 110 by a supply line.

In one embodiment, the trough 218 may be isolated by dividers 330 (shown in phantom in FIG. 3) that separate the trough 218 into a plurality of zones 332. Each zone 332 may contain a desired amount of metal precursor to receive the reacting gas from the channel 216. It is contemplated that the trough 218 may be divided into different shapes, configurations, or reacting areas by a variety of dividers to meet different process requirements.

FIG. 4 depicts a cross section view of a metal precursor container 110 disposed in the hydride vapor phase epitaxy (HVPE) process chamber 100 of FIG. 1. In operation, a chamber lid 414 is disposed to the top of the chamber body 102 to maintain the processing pressure at a desired degree of vacuum. A gas distribution plate 402 is attached to the chamber lid 424 to supply different process gases to the processing region 116 of the chamber 100. In one embodiment, the gas distribution plate 402 may supply a carrier gas utilized to direct the reacting gas flowing from the metal precursor container 110 or from the gas dispense assembly 112 to a reacting zone 450 above an upper surface 418 of the substrate 108. The gases may be provided, at least in part, to the gas distribution plate 402 from the ports 138, 134.

The substrate carrier 106 is rotated by the power supply 480 so that each substrate 108 disposed around the substrate carrier 106 may be alternatively rotated into the reaction zone 450, thereby enhancing film growth and uniformity. Additionally, the heating elements 478 embedded in the substrate support assembly 104 maintain the substrate temperature at a desired processing temperature, thereby promoting the reacting rate for the deposition process.

During processing, a metal precursor 404 is disposed within the trough 218 of the elongated body 212. A container lid 408 is disposed on the metal precursor container 110 to confine the reacting gas flow in a desired flow path through the container 110. As the first reacting gas is supplied to the channel 216 of the container 110, the first reacting gas flows through an inlet port 420 defined between the groove 210 and the container lid 408, as shown by arrow 406. In some embodiments, at least one baffle 410 extends from a bottom surface of the container lid 408 toward the metal precursor 404 disposed in the elongated body 212. The baffle 410 extends into the upper region of the trough 218 and creates a tortuous path for the first reacting gas flowing through the body 212, thereby increasing the residence time and flow disturbance of the first reacting gas over the metal precursor 404. In some embodiments, a maze-lie wall, rows of tubes, spiral wire, coiled wire and other different types of configurations may be disposed in the upper region of the trough 218 above the metal precursor 404 to increase gas turbulence and extend the flow path. Alternatively, the baffle 410 and/or other types of flow path increasing elements may extend into a predetermined depth into the metal precursor 404 to create bubbles or foam that increases the surface area of the metal precursor 404 exposed to the first reacting gas. In yet another embodiment, the baffle 410 and/or other types of flow path increasing elements may be rotated to enhance the gas circulations in the upper region of the trough 218. In embodiments where the baffle 410 and/or other types of flow path increasing elements extends into the metal precursor 404, the baffle 410 may be moved and/or rotated so that the metal precursor 404 is agitated to increase exposed surface of the metal precursor to the first reacting gases.

The second wall 204 has a height slightly lower than the height of the first wall 202 of the elongated body 212. As the container lid 408 covers across the elongated body 212, an outlet port 422 is defined between the upper surface of the second wall 204 and the container lid 408 due to the height difference between the first wall 202 and the second wall 204. The height of the second wall 204 of the body 212 may be selected to assist in regulating the amount of first reacting gas flow, now in reacted with the metal to from a metal containing vapor, passing through the outlet port 422, thereby efficiently controlling the gas flow rate to the reacting zone 450.

The container lid 408 has an end 460 extending outwardly across the second wall 204 to a lip 412. The lip 412 extends downward adjacent the recess 206 defined in the second wall 204. A slot 462 is defined between the second wall 204 and an end 464 of lip 412 across the recess 206. The width of the slot 462 may be configured by selecting a length of the lip 412 of the container lid 408. In embodiments where a greater amount of metal containing vapor is desired, the width of the slot 462 may be larger to facilitate a greater volume of gas flow therethrough.

The lip 412 may have a length less the length of the second wall 204, thereby defining an opening 424 between the end 464 of the lip 412 and the body 212. The dimension and/or shape of the opening 424 may be varied according to different process requirements by increasing or decreasing the length of the lip 412. Alternatively, the dimension of the opening 424 may be varied in accordance with different ends 464 of the lip 412 as described further below with reference to FIGS. 5A-C.

In embodiments where a first reacting gas is HCl and the metal precursor 404 is liquid Ga metal, the HCl gas may be supplied to the channel 216 through the inlet port 420 to the trough 218 of the elongated body 212. The HCl gas reacts with Ga metal, forming GaCl vapor. The GaCl vapor is subsequently transported through the outlet port 422 into the slot 462 defined in the recess 206. The GaCl vapor exits the body 212 through to the opening 424. A second reacting gas, such as a Group V gas, for example, NH₃ gas, is supplied from a gas port 416, located out of the container 100. The second reacting gas flows below the metal precursor container 110, as shown in phantom by arrow 416, to the reacting zone 450 above the substrate surface 418. In one embodiment, a first carrier gas may be optionally used to transport the first and/or the second reacting gas to the reacting zone 450. A second carrier gas 498, such as N₂, H₂, Ar He, supplied from the ports 138, 134, or other source, such as from the gas distribution plate 402, is supplied to the chamber 100. The second carrier gas directs the GaCl vapor and NH₃ gas toward the substrate surface. The NH₃ gas reacts with the GaCl vapor to form a GaN film on the substrate surface 418. The growth rate of the GaN film may be determined by reacting temperature, reacting vapor concentration, gas flow rate, and ratio of gas vapor mixing. The process may be terminated as a desired thickness of GaN is reached. In one embodiment, the GaN film is deposited to a thickness between about 0.5 μm and about 100 μm.

During processing, several process parameters may be regulated. In one embodiment, HCl gas supplied from the gas supplying assembly 122 to the metal precursor container 110 may have a flow rate at between about 5 sccm and about 1 slm. The second carrier gas supplied from the gas distribution plate 402 into the processing region 116 may have a flow rate at between about 0 sccm and about 5 slm. Suitable examples of the carrier gas include H₂, N₂, Ar, He and combinations thereof. Optionally, the first carrier gas may be supplied with the NH₃ or HCl into the reacting region 450 at a flow rate between about 0 and about 20 slm.

The substrate temperature may be controlled between about 700 degrees Celsius and about 1400 degrees Celsius. The metal precursor container 110 may be controlled at a temperature between about 900 degrees Celsius and about 1200 degrees Celsius.

FIGS. 5A-C depict alternative embodiments of ends 543 of a lid 542 enclosing a metal precursor container 500. The metal precursor container 500 is similar to the metal precursor container 110 of FIGS. 1-4, having an elongated body 554 defined by a first wall 510, a second wall 506, and a bottom wall 548. A channel 504 is defined in the first wall 510 of the container 500.

A heating element 524 may be interfaced with the body 554 of the container 500 to control the temperature of metal precursor 522 disposed therein. A lamp assembly 528 may be optionally disposed around and/or below the metal precursor container 500 to enhance control of the container temperature, thereby substantially preventing temperature gradients across the metal precursor container 500. Alternatively, the lamp assembly 528 may be disposed below the container lid 542 to provide radiant heat to the metal precursor. A temperature detector 552 similar to the temperature detector 112 of FIG. 3 is coupled to the metal precursor container 500 to monitor the container temperature. The temperature detector 552 is coupled a controller 526 to provide a feed back loop to real time control the temperature of the heating element 524 and the lamp assembly 528, thereby assisting precise control of the container temperature.

The container lid 542 includes a lip 544 having the end 546 facing downwardly toward an upper surface 550 of a recess 540. The end 546 may have a sloped surface 516 to direct the flow of vapor exit the body 554. Alternatively, the end 546 may have a flat, horizontal surface 515, as shown in FIG. 5B, a rounded surface 520 as shown in FIG. 5C, or other suitable profile.

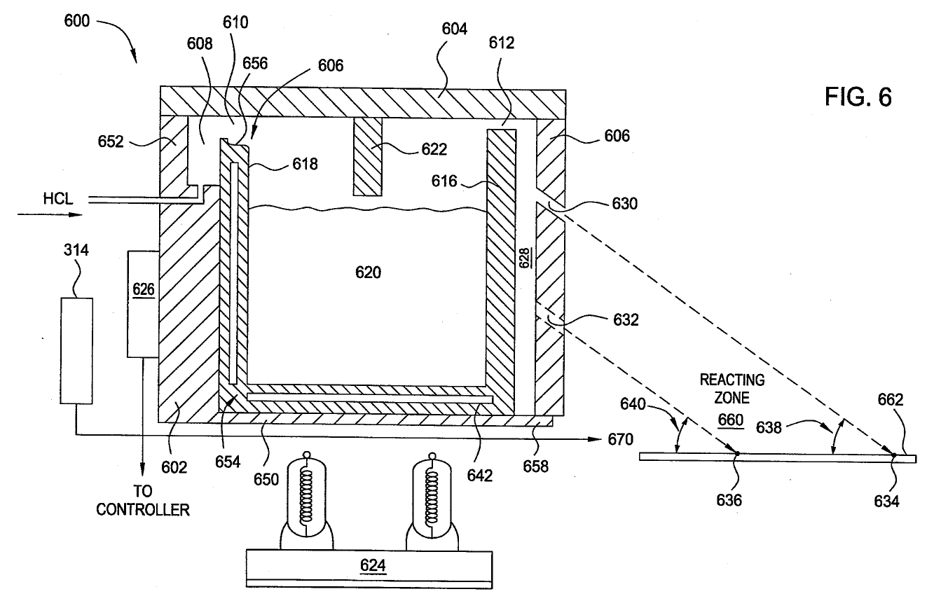

FIG. 6 depicts another embodiment of a metal precursor container 600 according to the present invention. The metal precursor container 600 includes a substantially L-shape support 602 and an elongated body 654 positioned thereon or inserted therein. The substantially L-shape support 602 has a bottom leg 650 and a standing wall 652. The standing wall 652 is in contact with a first wall 618 of the elongated body 654. A channel 608 is defined between the standing wall 652 and the first wall 618. An inlet port 610 is defined between a groove 656 formed on an upper surface of the first wall 618 and a container lid 604. An outlet port 612 is defined between a second wall 616 of the elongated body 654 and the container lid 604. A baffle 622 is attached to the container lid 604 extending toward and facing metal precursor 620 disposed in the container 600.

A blocking wall 606 is disposed on an end 658 of the bottom leg 650 and below the container lid 604. The blocking wall 606 is spaced from the second wall 606 so that a slot 628 is defined therebetween. The blocking wall 606 may be part of the lid 606, the support 602, or be a separate component. The blocking wall 606 has a substantially horizontal slot or plurality of openings 630 to facilitate vapor flowing out of the container 600 into a reacting zone 660 defined over a substrate surface 662. The plurality of openings 630 may elevated above from the substrate surface, thereby allowing the reacting gas flowing therethrough to be injected on a desired region 634 on the substrate surface 662. The trajectory of the vapor exiting the opening 630 may be controlled and be selected at an appropriate injection angle 638. Alternatively, a plurality of openings 632 formed in the blocking wall 606 may be located at different heights and/or different injection angles 640 to create different reacting region 636. Similar to the configuration described above in FIG. 4, a second reacting gas may be supplied below the container 600 to the reacting zone 660 on the substrate surface 662.

As the openings 630, 632 formed on the blocking wall 606 may be formed at different heights on the blocking wall 606, gave different configuration, angle, distribution, and number, the adjustable profile, thickness and uniformity of the deposited Group III nitride film may be tailored to meet specific design requirements. The configuration of the openings 630, 632 formed in the blocking wall 606 may be readily changed by switching to another blocking wall.

Thus, an improved method and apparatus for depositing a Group III nitride using a hydride vapor phase epitaxy (HVPE) process are provided. The improved apparatus advantageously facilitates reproducible and robust Group III nitride film deposition, thereby enhancing film to film crystal structure reproduction.

While the foregoing is directed to embodiments of the present invention, other and further embodiments of the invention may be devised without departing from the basic scope thereof, and the scope thereof is determined by the claims that follow.

What is claimed is:

1. An apparatus for a hydride vapor phase epitaxy process, comprising:
an elongated body having a trough defined between a first and a second wall;
a channel formed in the first wall configured to provide a gas to the trough; and
an inlet port formed in the body coupled to the channel.

2. The apparatus of claim 1, wherein the first wall extends greater a distance above a bottom wall of the body than the second wall.

3. The apparatus of claim 1, further comprising:
a plurality of grooves formed on an upper surface of the first wall opening the chamber to the trough.

4. The apparatus of claim 1, wherein the channel is open to an upper surface to an upper surface of the first wall.

5. The apparatus of claim 1, further comprising:
at least one baffle disposed into the trough.

6. The apparatus of claim 2, wherein the bottom wall extends beyond the second wall forming the recess along the second wall.

7. The apparatus of claim 1, further comprising:
a lid covering the trough.

8. The apparatus of claim 7, wherein the lid further comprises:
at least one baffle attached to the lid extending into the trough.

9. The apparatus of claim 7, wherein the lid further comprises:
a lip extending downward and covering at least a portion of the second wall.

10. The apparatus of claim 9, wherein the lip defines a slot between the lip and the second wall.

11. The apparatus of claim 9, further comprising:
an opening defined between a lower end of the lip and an upper surface of the bottom wall in the recess.

12. The apparatus of claim 1, further comprising:
a recess formed in the outer surface of the second wall.

13. The apparatus of claim 2, further comprising:
a blocking wall disposed adjacent the second wall; and
a gas passage opened to the trough defined between the bottom and the second wall

14. The apparatus of claim 1, further comprising:
a lamp assembly arranged to heat the body.

15. The apparatus of claim 1, wherein the body further comprises:
a heating element.

16. The apparatus of claim 1, further comprising:
a liquid injector coupled to the trough.

17. An apparatus for a hydride vapor phase epitaxy process, comprising:
a chamber;
a substrate support assembly adapted to receive a substrate disposed thereon;
an elongated body having a trough defined between a first and second walls disposed in the chamber proximate the substrate support assembly;
an outer inlet port formed in the elongated body;
a gas dispense assembly attached to the elongated body; and
an inlet port and an outlet port each formed above the first and the second wall of the trough.

18. The apparatus of claim 17, further comprising:
a bottom wall defined between the first wall and the second wall.

19. The apparatus of claim 17, wherein the bottom wall extends beyond the second wall defining a recess along the outer surface of the second wall:

20. The apparatus of claim 17, further comprising:
a channel defined in the first wall.

21. The apparatus of claim 17, further comprising:
a lid adapted to dispose on the top of the trough.

22. The apparatus of claim 17, further comprising:
at least a baffle disposed on the trough.

23. The apparatus of claim 17, further comprising:
a gas supply assembly disposed in the chamber.

24. The apparatus of claim 22, further comprising:
a heating element disposed in the chamber adapted to heat the trough.

25. The apparatus of claim 22, further comprising:
a liquid metal precursor disposed in the trough.

26. The apparatus of claim 22, wherein the gas dispense assembly has ports formed on a bottom surface of the assembly adapted to supply a first reacting gas to the chamber below the elongated body.

27. The apparatus of claim 17, wherein a second reacting gas is supplied to the trough the outer inlet port formed in the elongated body.

28. A method for depositing a Group III nitride by a hydride vapor phase epitaxy process, comprising:
providing Group III metal liquid precursor in a container disposed in a chamber;
flowing a halogen containing gas across the container to form a Group III metal halide vapor to a reacting zone in the chamber; and
mixing the Group III metal halide vapor with a Group V gas supplied in the chamber in the reacting zone.

29. The method of claim 28, further comprising:
forming a Group III-V layer on a substrate surface.

30. The method of claim 28, wherein the step of flowing the halogen containing gas further comprising:
flowing a chlorine containing gas through a tortuous path defined in the trough.

31. The method of claim 30, wherein the tortuous path is defined by a baffle attached to a lid covering the container.

32. The method of claim 30, wherein the chlorine containing gas is HCl gas.

33. The method of claim 28, wherein the step of providing Group III metal liquid precursor further comprises:
heating the metal precursor.

34. The method of claim 30, wherein the Group V gas is a nitrogen containing gas.

35. The method of claim 34, wherein the nitrogen containing gas is NH₃.

36. The method of claim 28, wherein the step of mixing the Group III metal halide vapor with the Group V gas further comprising:
supplying the Group V gas into the chamber from a bottom of the container.

37. The method of claim 28, wherein the Group III metal is at least one of Ga, Al or In.
